(19) United States
(12) Patent Application Publication
(10) Pub. No.: US 2008/0233906 A1
(43) Pub. Date: Sep. 25, 2008

(54) FREQUENCY CONVERTER, RADIO RECEIVER

(75) Inventors: Toshiya Mitomo, Yokohama-shi (JP); Rui Ito, Chigasaki-shi (JP); Asuka Maki, Kawasaki-shi (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/926,925

(22) Filed: Oct. 29, 2007

(30) Foreign Application Priority Data
Mar. 19, 2007 (JP) 2007-70358

(51) Int. Cl. H03D 7/16; H03B 19/00

(52) U.S. Cl. 455/131; 327/116

(57) ABSTRACT

Disclosed is a frequency converter including: a passive type analog multiplier configured to output a multiplication result in a current; a buffer outputting a buffering current by buffering the current of the multiplication result; and a current-voltage converter current-voltage converting the buffering current. Alternately, disclosed is a frequency converter including: a passive type analog multiplier configured to output a multiplication result in a current; a buffer outputting a buffering current by buffering the current of the multiplication result; and an integrator integrating the buffering current to output a voltage.

### CROSS-REFERENCE TO RELATED APPLICATIONS

This application is based upon and claims the benefit of priority from the prior Japanese Patent Application No. 2007-70358, filed on Mar. 19, 2007; the entire contents of which are incorporated herein by reference.

### BACKGROUND OF THE INVENTION

1. Field of the Invention

The present invention relates to a frequency converter suitable for use to convert an RF signal to low-frequency with low-noise, and to a radio receiver using the same.

2. Description of the Related Art

In recent years, a development of a radio terminal has been made vigorously, and a small-sizing and price-reduction thereof have been advancing. In the radio terminal, if an RF analog process is realized by a CMOS IC such as one used in a baseband digital process portion, the CMOS IC provides one of very effective means to realize a small-sizing and price-reduction such as to make a digital/analog process be handled in one IC chip. In the RF analog process, low-noise characteristics are required for devices including the frequency converter because a weak signal received by an antenna is demodulated into a baseband signal.

It is known that a large low frequency flicker (1/f) noise is outputted from a switching transistor when an active double balance type frequency converter including CMOS elements is used as the frequency converter. Accordingly, when this frequency converter is applied to a direct conversion receiver whose output frequency becomes in a vicinity of DC, the low-noise characteristics to a degree achieved when a bipolar transistor is used, cannot be obtained.

As a method to solve the above-stated problem, it is known that a passive double balance type CMOS frequency converter is used. In the passive double balance type, a bias current is not to be flowed into the switching transistor, and therefore, it becomes possible to suppress a generation of the above-stated noise (for example, refer to the document: W. Redman-White, D. M. W. Leenaerts, “1/f noise in passive CMOS mixers for low and zero IF integrated receivers,” European Solid-State Circuit Conference, Villach, Austria, September 2001). Besides, this type of frequency converter, different from the active double balance type, does not have a circuitry in which transistors are loaded longitudinally, and therefore, it also has an advantage such that an application of a fine CMOS process having low withstand voltage is easy.

An output of the passive double balance type frequency converter is current as it is, and therefore, an intervention of some current-voltage conversion means is generally required to connect to an analog baseband process portion (concretely speaking, a lowpass filter, a variable gain amplifier, and soon) at a subsequent stage. In general, a current-voltage converter can be constituted by, for example, an operational amplifier using CMOS elements and a feedback resistance connected to this operational amplifier (instead of the feedback resistance there also is a case of a parallel connection of resistance and capacitance). Accordingly, output current of the CMOS frequency converter is flowed to the feedback resistance, and becomes a voltage output at an output side of the operational amplifier. This voltage output can be supplied to the analog baseband process portion at the subsequent stage.

If a case is considered when both of differential MOS transistors used in the CMOS frequency converter become ON state transiently (a state in which a resistance Rt in a current passing becomes low), it becomes a state in which an equivalent input noise source for the operational amplifier is connected to the operational amplifier with this resistance Rt as an input resistance, in a configuration in which the CMOS frequency converter and the current-voltage converter as stated above are used. Consequently, the noise is outputted from the current-voltage converter multiplied by Rk/Rt times.

In general, a feedback resistance Rk is in an order of k Ω to obtain a predetermined conversion gain, and an ON resistance of a switch is several Ω to dozens Ω. Accordingly, the noise is amplified very largely. Namely, it can be said that the passive double balance type CMOS frequency converter is low noise as a stand-alone characteristic thereof, but the noise characteristic as a total deteriorates when it is combined with the analog baseband process portion at the subsequent stage. Besides, similarly, when an AD converter such as a delta sigma (ΔΣ) type AD converter is connected at the subsequent stage, a large noise is generated because an integrator at a first stage thereof has an approximately similar configuration to the current-voltage converter.

### BRIEF SUMMARY OF THE INVENTION

A frequency converter according to an aspect of the present invention, includes: a passive type analog multiplier configured to output a multiplication result in a current; a buffer outputting a buffering current by buffering the current of the multiplication result; and a current-voltage converter current-voltage converting the buffering current.

Namely, a current output type and passive type device is used for the analog multiplier having a frequency conversion function, and the current-voltage converter is used to obtain a voltage output. Here, the buffer buffering the current generated by the analog multiplier and generating the buffering current is provided between the analog multiplier and the current-voltage converter, and the buffering current through this buffer is guided to the current-voltage converter. Accordingly, an equivalent series resistance Rs for an input end of the current-voltage converter becomes an output impedance of the buffer, and it becomes possible to realize a very high value compared to the above-described ON resistance of a switch, and to largely suppress a gain for a noise of an equivalent input noise source of the current-voltage converter. Consequently, it is useful as the frequency converter converting an RF signal into low frequency.

Besides, a frequency converter according to another aspect of the present invention, includes: a passive type analog multiplier configured to output a multiplication result in a current; a buffer outputting a buffering current by buffering the current of the multiplication result; and an integrator integrating the buffering current to output a voltage.

Namely, a current output and passive type device is used for the analog multiplier having a frequency conversion function, and the integrator is used to obtain a voltage output. Here, the buffer buffering the current generated by the analog multiplier and generating the buffering current is provided between the analog multiplier and the integrator, and the buffering current through this buffer is guided to the integrator. Accordingly, an equivalent series resistance Rs for an input end of the integrator becomes an output impedance of the buffer, and it becomes possible to realize a very high value compared to the above-described ON resistance of a switch, and to largely suppress a gain for a noise of an equivalent input noise source of the integrator. Consequently, it is useful as the frequency converter converting an RF signal into low frequency.

Besides, a radio receiver according to still another aspect of the present invention includes: an antenna capturing radio waves to output an RF signal; a quadrature oscillator outputting two oscillation waveforms orthogonal with each other; a first frequency converter having: a passive type first analog multiplier configured to output a multiplication result of a first signal and a second signal in a first current; a first buffer outputting a first buffering current by buffering the first current; and a first current-voltage converter current-voltage converting the first buffering current, wherein the RF signal is designated as the first signal, one of the two oscillation waveforms is designated as the second signal, and a first baseband signal is obtained at an output of the first current-voltage converter; a second frequency converter having: a passive type second analog multiplier configured to output a multiplication result of a third signal and a fourth signal in a second current; a second buffer outputting a second buffering current by buffering the second current; and a second current-voltage converter current-voltage converting the second buffering current, wherein the RF signal is designated as the third signal, another of the two oscillation waveforms is designated as the fourth signal, and a second baseband signal is obtained at an output of the second current-voltage converter; and a baseband signal processor configured to signal-process the first and second baseband signals.

This radio receiver is a receiver in which the above-stated frequency converters are used as a demodulator by orthogonal two axes.

### BRIEF DESCRIPTION OF THE SEVERAL VIEWS OF THE DRAWINGS

FIG. 1 is a configuration diagram showing a frequency converter according to an embodiment.

FIG. 2 is a configuration diagram showing the frequency converter shown in FIG. 1 more concretely.

FIG. 3 is a configuration diagram showing a case in which a frequency converter according to another embodiment is disposed at an input side of a ΔΣ type AD converter.

FIG. 4 is a block diagram showing a configuration of a radio receiver according to an embodiment.

### DETAILED DESCRIPTION OF THE INVENTION

### Description of Embodiments

Embodiments of the present invention will be described with reference to the drawings, but these drawings are provided only for an illustrative purpose and by no means are intended to limit the present invention.

As a form of a frequency converter, the analog multiplier may have two sets, that is a first and second sets, of a pair of CMOS transistors which are switched complementarily in accordance with a variation of one of a first signal and a second signal inputted as a subject of multiplication, and in the analog multiplier a complementary current may be supplied to the first set of CMOS transistors and the second set of CMOS transistors in accordance with a variation of another of the first signal and the second signal. Namely, a double balance type analog multiplier is used.

Besides, as a form, the buffer may be a common-gate amplifier. According to the common-gate amplifier, it is possible to perform a signal input by current, and to significantly heighten output impedance compared to the aforementioned switch-on resistance, and therefore, it is easily possible to largely suppress a gain for a noise of an equivalent input noise source of the current-voltage converter or the integrator.

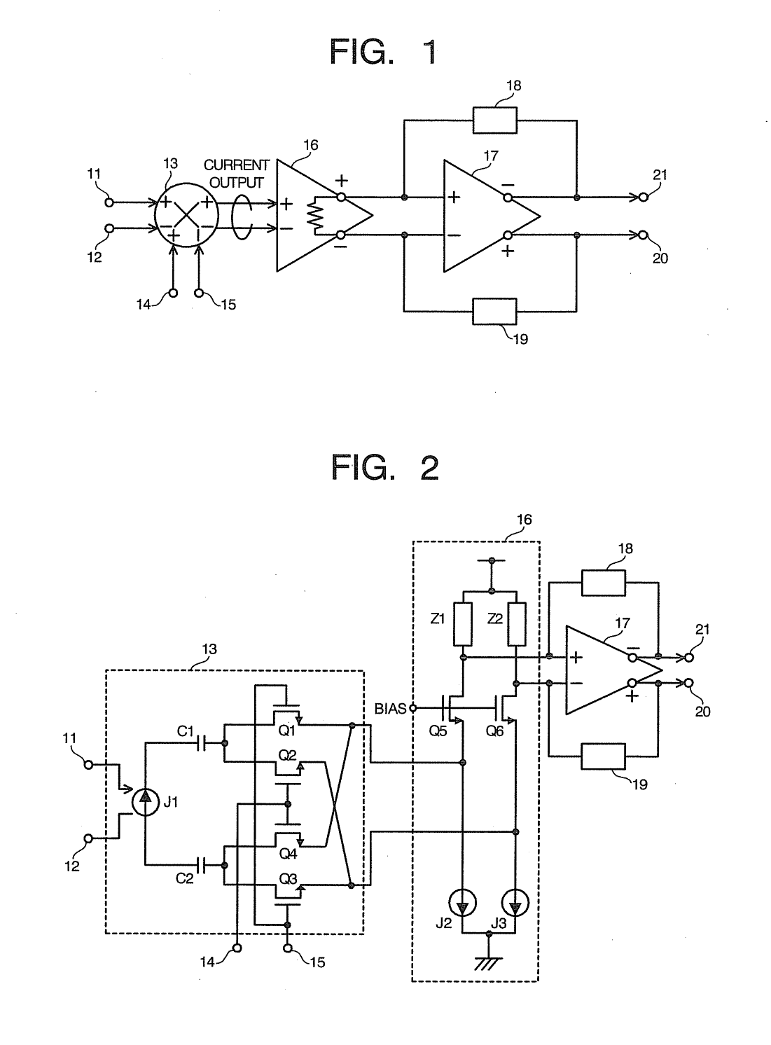

Based on the above, embodiments are described hereinafter with reference to the drawings. FIG. 1 shows a frequency converter according to an embodiment. As shown in FIG. 1, this frequency converter has an analog multiplier 13, a buffer 16, an operational amplifier 17, and feedback resistances 18, 19.

The analog multiplier 13 receives a signal (voltage) to be multiplied from signal-to-be-multiplied input terminals 11, 12 (the terminal 11 is a plus side, and the terminal 12 is a minus side) in a differential manner. Besides, the analog multiplier 13 receives a multiplying signal (voltage) from multiplying signal input terminals 14, 15 (the terminal 14 is a plus side, and the terminal 15 is a minus side) in a differential manner. The signal to be multiplied and the multiplying signal are multiplied inside of the analog multiplier 13 to be a signal corresponding to a multiplication result, which is supplied to the buffer 16 as a differential current signal.

The supplied differential current signal is buffered at the buffer 16, and a buffering current thereof is outputted in a differential manner. The operational amplifier 17 and the feedback resistances 18, 19, to which the output current of the buffer 16 is supplied, constitute a current-voltage converter. Namely, almost all of the current outputted from the buffer 16 flows to the feedback resistances 18, 19 because input impedances of positive/negative input terminals of the operational amplifier 17 are large enough respectively. Thus, output voltages in proportion to the current are respectively generated at positive/negative output terminals of the operational amplifier 17. These voltages are guided to output terminals 20, 21.

In the frequency converter as stated above, the noise of the equivalent input noise source of the operational amplifier 17 is to be outputted while amplified by Rf/Rs times wherein the output impedance of the buffer 16 is Rs, and the feedback resistances 18, 19 are respectively Rf. Here, it is possible to set the output impedance Rs of the buffer 16 very large owing to a nature of the buffer. Accordingly, it is possible to realize the frequency converter with low-noise characteristics by making Rf/Rs small. Differences are obvious when it is compared with a case in which the buffer 16 is not provided and the output current of the analog multiplier 13 is directly connected to the current-voltage converter constituted by the operational amplifier 17 and the feedback resistances 18, 19 (in particular, when all of switches inside of the analog multiplier 13 are turned on). Namely, when the buffer 16 is not provided, a state in which the output impedance of the analog multiplier 13 becomes very low occurs, and therefore, the noise of the equivalent input noise source of the operational amplifier 17 is amplified largely.

Incidentally, the noise generated from the buffer 16 in itself exists in general, but a current gain of the buffer 16 is not necessarily be large, and therefore, an effect of realizing the low noise owing to an installation of the buffer 16 is remarkably large, in total.

Next, FIG. 2 shows the frequency converter shown in FIG. 1 more concretely. In FIG. 2, the same reference numerals and symbols in FIG. 1 are used to designate the same and corresponding elements, and the description thereof will not be given.

As shown in FIG. 2, the analog multiplier 13 has a voltage control type current source J1 in which the differential voltage from the input terminals 11, 12 is a control voltage (namely, the current source J1 is a transconductor), capacitors C1, C2, a pair of CMOS transistors Q1, Q2, and another pair of CMOS transistors Q3, Q4.

Besides, the buffer 16 has a common-gate amplifier constituted by a CMOS transistor Q5, a current source J2, and a load impedance Z1, and another common-gate amplifier constituted by a CMOS transistor Q6, a current source J3, and a load impedance Z2.

In the analog multiplier 13, a direction of an output current of the current source J1 alters by each half-wave and the next half-wave in accordance with a variation of the differential voltage from the input terminals 11, 12. The alternate current as stated above is supplied to a first switching pair constituted by the transistors Q1, Q2 and a second switching pair constituted by the transistors Q3, Q4 via the capacitors C1, C2 so that the directions of the currents are to be in an opposite direction with each other. At the transistors Q1, Q2, the transistor to be turned on alters by each half-wave and the next half-wave in accordance with a variation of the differential voltage from the input terminals 14, 15. Besides, also at the transistors Q3, Q4, the transistor to be turned on alters by each half-wave and the next half-wave in accordance with the variation of the differential voltage from the input terminals 14, 15, similarly.

Thereby, a current is generated at a connection node of sources of the transistor Q1 and transistor Q4 so as to correspond to a product (logical product) of the variation of the differential current from the current source J1 and the variation of the differential voltage from the input terminals 14, 15. Besides, a current is also generated at a connection node of sources of the transistor Q3 and transistor Q2 so as to correspond to a product of a completely opposite polarity from the above-stated product. These generated currents become a differential current output of the analog multiplier 13.

A common bias voltage is supplied to respective gates of the transistors Q5, Q6 of the common-gate amplifier used as the buffer 16, and the output currents of the analog multiplier 13 are guided to sources of the transistors Q5, Q6. These guided currents do not flow to the ground because of the current sources J2, J3, and flows from the sources to the drain sides of the transistors Q5, Q6. The currents flowed toward the drain sides are current inputted to the feedback resistances 18, 19 avoiding the load impedances Z1, Z2 because the input impedance of the current-voltage converter constituted by the operational amplifier 17 and the feedback resistances 18, 19 is low. The impedances determined by the load impedances Z1, Z2 and the transistors Q5, Q6 correspond to the output impedance Rs of the buffer 16, respectively.

This mode is a CMOS frequency converter constituting a double balance type by the transconductor having the current source J1, and the pair of transistors Q1, Q2 and the pair of transistors Q3, Q4. Besides, it is a passive type in which constant current (bias current) does not flow in the pair of transistors Q1, Q2 and the pair of transistors Q3, Q4, and therefore, a generation of a large low-frequency flicker (1/f) noise can be prevented. Accordingly, it is particularly suitable for a case when the frequency converter is applied to a direct conversion receiver in which an output frequency becomes in a vicinity of DC. Besides, the analog multiplier 13 does not have a circuitry in which the transistors are loaded longitudinally, and therefore, it is easy to apply a fine CMOS process having low withstand voltage.

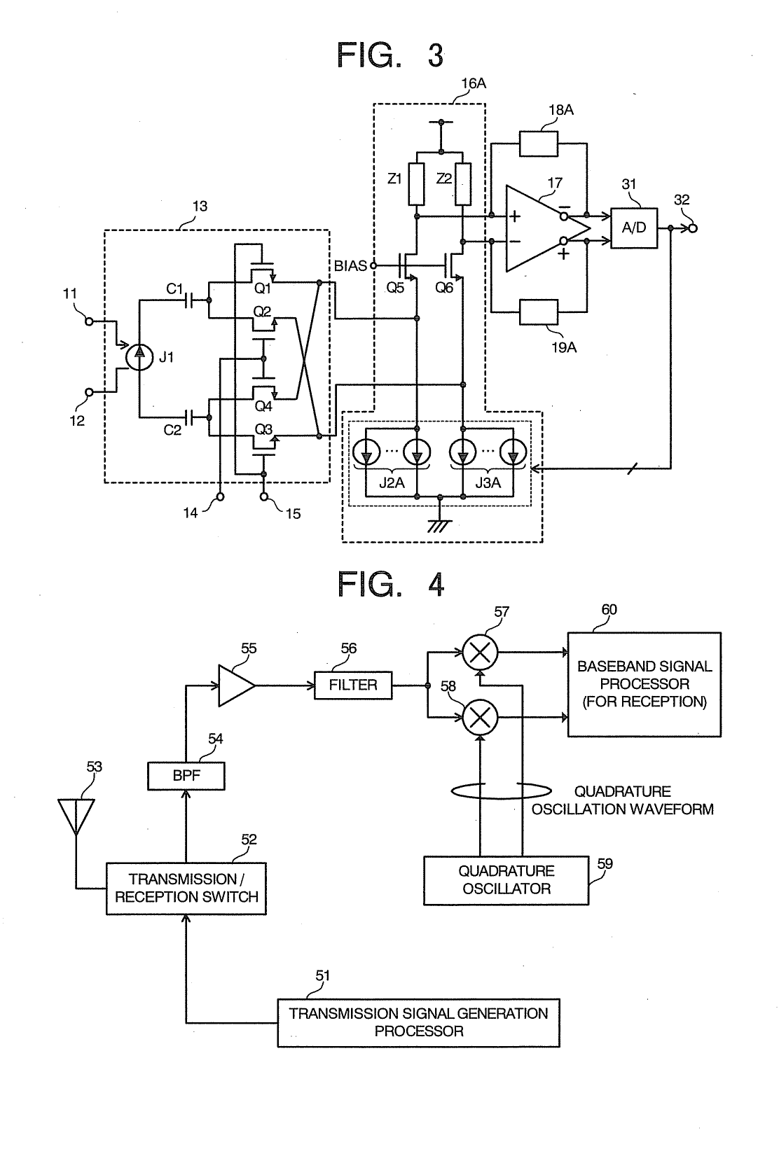

Next, FIG. 3 shows a configuration when a frequency converter according to another embodiment is disposed at an input side of a ΔΣ type AD converter. In FIG. 3, the same reference numerals and symbols in the already described drawings are used to designate the same and corresponding elements, and the description thereof will not be given.

In this mode, an integrator constituted by the operational amplifier 17, and feedback impedance elements 18A, 19A is provided at an output of a buffer 16A. A differential voltage output of the integrator is guided to a digitizing circuit 31. In the digitizing circuit 31, the inputted differential voltage is converted into a digital signal with a predetermined sample frequency. This digital signal output is guided to a digital signal output terminal 32.

A capacitor or a parallel connection of the capacitor and a high resistance resistor is used for the feedback impedance elements 18A, 19A to obtain integral characteristics. Almost all of the currents outputted from the buffer 16A flow into the feedback impedance elements 18A, 19A also in case of the integrator as stated above, because the input impedance of the operational amplifier 17 is large, similarly to the case of the current-voltage converter shown in FIG. 2.

The digital signal output of the digitizing circuit 31 is also guided to current sources J2A, J3A provided at the buffer 16A. It is possible to make both of the current sources J2A, J3A to be, for example, a parallel connection of plural current sources. ON/OFF states of each of these plural current sources are controlled in accordance with a value shown by the guided digital signal, and bias currents of the transistors Q5, Q6 are adjusted as a total thereof. A noise shaping becomes possible by performing a ΔΣ modulation under the state as stated above.

An influence of the equivalent input noise source of the operational amplifier 17 used for the integrator is effectively suppressed by enlarging the load impedances Z1, Z2 of the buffer 16A sufficiently also when the frequency converter is applied to the AD converter, as stated above.

Next, a case when the above-described frequency converter is applied to a radio transmitter/receiver such as a cellular phone handset is described with reference to FIG. 4. FIG. 4 shows a configuration of a radio receiver according to an embodiment (note that it is a multipurpose device with a radio transmitter). In this example, a TDD (time division duplex) method in which a switching of transmission/reception is performed by time division is shown, but it is not limited to the above as the embodiment, and an FDD (frequency division duplex) method can also be adopted.

As shown in FIG. 4, this multipurpose device has a transmission signal generation processor 51, a transmission/reception switch 52, an antenna 53, a band-pass filter 54, a low-noise amplifier 55, a band-pass filter 56, frequency converters 57, 58, a quadrature oscillator 59, and a baseband signal processor (for reception) 60. The frequency converters according to the above-described respective embodiments can be used respectively for the frequency converters 57, 58.

Operations of this multipurpose device are described with functions of each component. Respective processes such as a generation of quadrature and in-phase baseband transmission signals, an orthogonal modulation of carrier waveforms by these signals and synthesis, and power amplification thereof are performed at the transmission signal generation processor 51. The power amplified signal is supplied to the antenna 53 under a state in which the transmission/reception switch 52 is switched to a transmission side of transmission and reception. The signal supplied to the antenna 53 is radiated as radio waves.

At the reception time, the signal radiated into the air as the radio waves is captured by the antenna 53, and guided to the band-pass filter 54 as an RF signal under a state in which the transmission/reception switch 52 is switched to a reception side. At the band-pass filter 54, undesired frequency components are removed, and the output is amplified at the low-noise amplifier 55 under the low-noise characteristics. The low-noise amplified RF signal is guided to the band-pass filter 56 so that the undesired frequency components are removed, and the RF signal being an output thereof is inputted to the two frequency converters 57, 58. These two frequency converters 57, 58 function as a quadrature demodulator.

Namely, at the frequency converters 57, 58, the inputted RF signal is demodulated by orthogonal two axes by using an oscillation waveform (called also as a local signal or a local oscillation signal) from the quadrature oscillator 59. This oscillation waveform has the same frequency with a carrier frequency of the inputted RF signal. A demodulated two-phased baseband signal obtained by the demodulation is guided to the baseband signal processor (for reception) 60, and a predetermined baseband process is performed at the baseband signal processor 60 to reproduce transmitted information.

In the radio receiver of this embodiment, the frequency converters according to the already described embodiments are used as the frequency converters 57, 58, and therefore, it is possible to convert the RF signal into the baseband signal with low noise.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A frequency converter, comprising:
a passive type analog multiplier configured to output a multiplication result in a current;
a buffer outputting a buffering current by buffering the current of the multiplication result; and
a current-voltage converter current-voltage converting the buffering current.

2. The frequency converter according to claim 1,
wherein the analog multiplier has two sets, that is a first set and a second set, of a pair of CMOS transistors complementarily switched in accordance with a variation of one of a first signal and a second signal inputted as a subject of multiplication, and in the analog multiplier a complementary current is supplied to the first set of CMOS transistors and the second set of CMOS transistors in accordance with a variation of another of the first signal and the second signal.

3. The frequency converter according to claim 1, wherein the buffer is a common-gate amplifier.

4. A frequency converter, comprising:
a passive type analog multiplier configured to output a multiplication result in a current;
a buffer outputting a buffering current by buffering the current of the multiplication result; and
an integrator integrating the buffering current to output a voltage.

5. The frequency converter according to claim 4,
wherein the analog multiplier has two sets, that is a first set and a second set, of a pair of CMOS transistors complementarily switched in accordance with a variation of one of a first signal and a second signal inputted as a subject of multiplication, and in the analog multiplier a complementary current is supplied to the first set of CMOS transistors and the second set of CMOS transistors in accordance with a variation of another of the first signal and the second signal.

6. The frequency converter according to claim 4, wherein the buffer is a common-gate amplifier.

7. A radio receiver, comprising:
an antenna capturing radio waves to output an RF signal;
a quadrature oscillator outputting two oscillation waveforms orthogonal with each other;
a first frequency converter having: a passive type first analog multiplier configured to output a multiplication result of a first signal and a second signal in a first current; a first buffer outputting a first buffering current by buffering the first current; and a first current-voltage converter current-voltage converting the first buffering current, wherein the RF signal is designated as the first signal, one of the two oscillation waveforms is designated as the second signal, and a first baseband signal is obtained at an output of the first current-voltage converter;
a second frequency converter having: a passive type second analog multiplier configured to output a multiplication result of a third signal and a fourth signal in a second current; a second buffer outputting a second buffering current by buffering the second current; and a second current-voltage converter current-voltage converting the second buffering current, wherein the RF signal is designated as the third signal, another of the two oscillation waveforms is designated as the fourth signal, and a second baseband signal is obtained at an output of the second current-voltage converter; and
a baseband signal processor configured to signal-process the first and second baseband signals.
